(19) United States
(12) Patent Application Publication
(10) Pub. No.: US 2015/0076187 A1
(43) Pub. Date: Mar. 19, 2015

(54) Antimicrobial Electronic Device Shell

(71) Applicant: Medline Industries, Inc., Mundelein, IL (US)

(72) Inventor: Jonathan A. Cohen, Highland Park, IL (US)

(73) Assignee: Medline Industries, Inc., Mundelein, IL (US)

(21) Appl. No.: 14/029,119

(22) Filed: Sep. 17, 2013

(51) Int. Cl. A45C 11/00; H05K 5/03

(52) U.S. Cl. CPC A45C 11/00; H05K 5/03; A45C 2011/003
USPC 224/191

(57) ABSTRACT

A shell can be conformally disposed over at least a majority of a backside of the housing of an electronic device of interest. By one approach this shell comprises, at least in part, a plastic interior and an antimicrobial metal exterior that covers at least a majority portion of the backside of the electronic device. The shell can be configured, for example, to snap-fit onto such a housing to thereby secure the shell in place during use and transit.

TECHNICAL FIELD

This invention relates generally to cases for electronic devices.

### BACKGROUND

Many electronic devices are both readily portable and intended for handheld usage. Examples in these regards include but are not limited to so-called smartphones and tablet/pad-styled computers. Such devices are often highly-capable digital processing and communications platforms and users can select from an ever-increasing number of applications by which the value and moment-to-moment relevance of any given device can be greatly increased.

Accordingly, electronic devices are used and increasingly relied upon by persons involved in a wide variety of professions, trades, and careers. This includes people in the medical services field including, for example, doctors, nurses, technicians, dieticians, counselors, and so forth. Unfortunately, the ease by which such electronic devices can be carried and the convenience offered via the connectivity and applications associated with such devices can also contribute to the spread of pathogens in a medical-services environment such as a hospital, clinic, or other care facility. In particular, the exterior surfaces of such devices can become the transport vector by which harmful microbes spread to new hosts.

### BRIEF DESCRIPTION OF THE DRAWINGS

The above needs are at least partially met through provision of the antimicrobial electronic device shell described in the following detailed description, particularly when studied in conjunction with the drawings, wherein:

FIG. 1 comprises a bottom plan view as configured in accordance with various embodiments of the invention;

FIG. 2 comprises a top plan view as configured in accordance with various embodiments of the invention;

FIG. 3 comprises a side elevational view as configured in accordance with various embodiments of the invention;

FIG. 4 comprises a side elevational view as configured in accordance with various embodiments of the invention;

FIG. 5 comprises a top-side elevational view as configured in accordance with various embodiments of the invention;

FIG. 6 comprises a bottom-side elevational view as configured in accordance with various embodiments of the invention;

FIG. 7 comprises a rear perspective view as configured in accordance with various embodiments of the invention;

FIG. 8 comprises a front perspective view as configured in accordance with various embodiments of the invention;

FIG. 9 comprises an exploded perspective view as configured in accordance with various embodiments of the invention;

FIG. 10 comprises an exploded perspective view as configured in accordance with various embodiments of the invention;

FIG. 11 comprises a bottom plan view as configured in accordance with various embodiments of the invention;

FIG. 12 comprises a side elevational view as configured in accordance with various embodiments of the invention;

FIG. 13 comprises a side elevational view as configured in accordance with various embodiments of the invention;

FIG. 14 comprises a top-side elevational view as configured in accordance with various embodiments of the invention;

FIG. 15 comprises a bottom-side elevational view as configured in accordance with various embodiments of the invention; and

FIG. 16 comprises a rear perspective view as configured in accordance with various embodiments of the invention.

Elements in the figures are illustrated for simplicity and clarity. Certain actions and/or steps may be described or depicted in a particular order of occurrence while those skilled in the art will understand that such specificity with respect to sequence is not actually required. The terms and expressions used herein have the ordinary technical meaning as is accorded to such terms and expressions by persons skilled in the technical field as set forth above except where different specific meanings have otherwise been set forth herein.

### DETAILED DESCRIPTION

Generally speaking, pursuant to these various embodiments a shell can be conformally disposed over at least a majority of a backside of the housing of an electronic device of interest. By one approach this shell comprises, at least in part, a plastic interior and an antimicrobial metal exterior that covers at least a majority portion of the backside of the electronic device. The shell can be configured, for example, to snap-fit onto such a housing to thereby secure the shell in place during use and transit.

If desired, antimicrobial metal can extend as well over other portions of the housing including, for example, one or more sides thereof. The antimicrobial metal can comprise, for example, one or more of copper, silver, and zinc (and/or alloys containing same). In many cases the electronic device includes one or more radio transceivers (as when, for example, the electronic device comprises a portable, wireless telephony device). In such cases the pattern of the antimicrobial metal can avoid areas that will lead to undue interference with the transmission and receipt of radio-frequency carriers by the electronic device. So configured the antimicrobial metal will not interfere with the ability of the electronic device to communicate wirelessly.

By one approach a portion of the shell (such as, for example, a portion of the antimicrobial metal) can include one or more raised surfaces configured to interpose between a majority of the shell and a surface upon which the shell is placed. This approach can help to mitigate opportunities for microbes to transfer between that surface and the shell.

So configured, the antimicrobial metal will typically serve to prevent the growth of microbes that transfer to its surface. Furthermore, antimicrobial metal will also typically kill most microbes within a relatively short period of time (in some cases in as little as thirty minutes). While such a case is not intended to serve as a substitute for proper sanitation and sterilization practices in a medical-services environment, these teachings can nevertheless greatly aid in mitigating or even preventing harmful microbes from moving about that environment via the electronic device notwithstanding regular handling of the device by the user and/or being placed on convenient surfaces in various locations during the course of the day.

These teachings are highly flexible in practice and will accommodate a wide variety of variations. By one approach, for example, the plastic portions of the shell can themselves comprise antimicrobial plastic. As another example the shell can further include, or can be used in conjunction with, a transparent shield (such as a so-called screen protector) that overlies a display as comprises a part of the electronic device. That transparent shield can itself include antimicrobial content such as, but not limited to, silver ions (present only in such quantity as to not unduly interfere with the transparency of the shield material).

As another example in these regards, these teachings will readily accommodate a variety of cosmetic treatments such as etching part or all of the exposed exterior surface of the antimicrobial metal to achieve a particular sheen or texture or to provide a graphic element such as text, a logo, or an icon or the like.

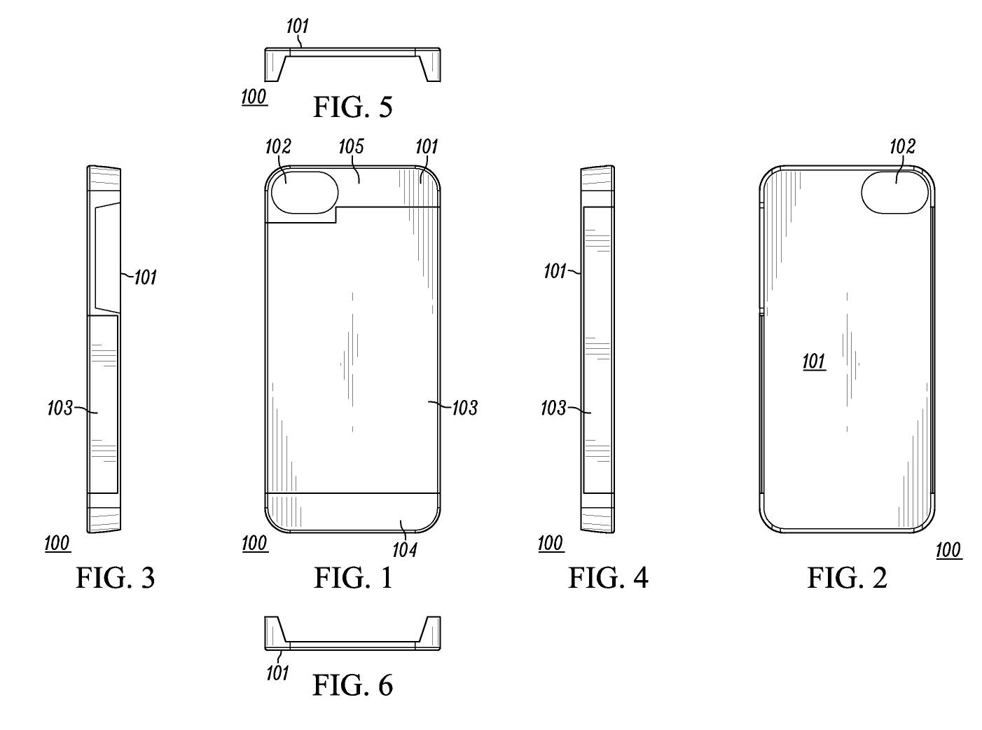

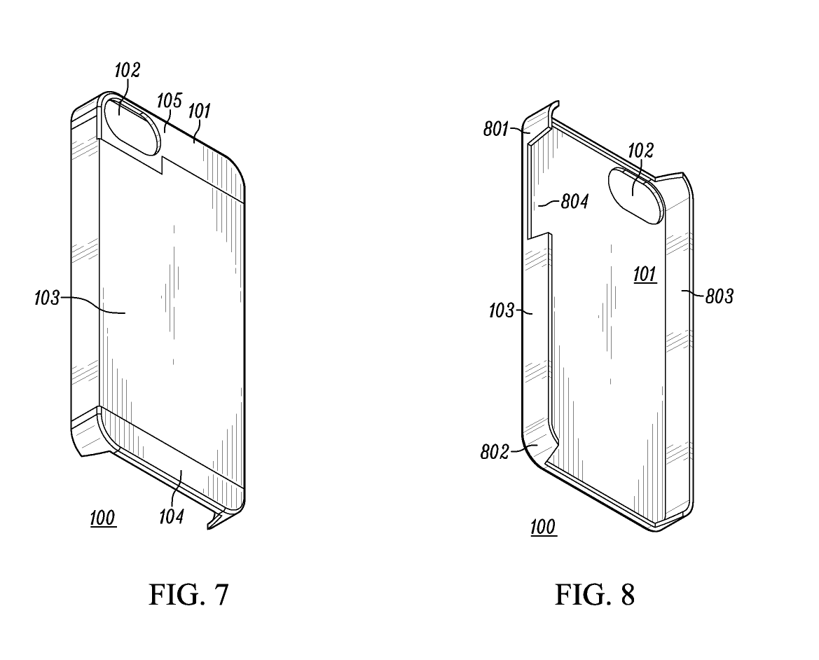

These and other benefits may become clearer upon making a thorough review and study of the following detailed description. Referring now to the drawings, and in particular to FIGS. 1-8, an illustrative example of a case 100 that accords with at least some of these teachings will now be presented.

This shell 100 is configured for use with a corresponding electronic device (not shown in FIGS. 1-8) that includes a housing. For the sake of an illustrative example it will be presumed here that the electronic device comprises a portable, wireless telephony device such as, but not limited to, a handheld smartphone such as the well-known iPhone®. The shell 100 is configured to be conformally disposed over at least a majority of a backside of the electronic device's housing. (As used herein, the word “majority” shall be understood to refer to covering more than fifty percent of the identified area.)

In the illustrated example, the case 100 includes a plate 101 that covers essentially all of the housing's backside with the exception of a small cutout 102. This cutout 102 provides an opening to accommodate a camera lens and light-emitting diode as comprise a part of the electronic device. Accordingly, in this example the plate 100 will cover more than ninety percent of the housing's backside when installed on the electronic device.

In the illustrated example the case 100 is further configured to extend over at least a portion of at least one side of the housing. In particular, in this example (and as is perhaps best shown in FIG. 8) the case 100 includes three side segments 801-803 that extend forwardly of the aforementioned plate 101 and that will extend over the corresponding sides of the electronic device's housing when installed thereon. In particular, these side segments 801-803 are configured to snap-fit the case 101 onto that housing. Accordingly, the case 100 can be readily installed by the end user and/or removed by the end user without the aid of special tools or training.

In the example of FIGS. 1-8, one of the aforementioned side segments 803 is essentially co-extensive with the entire corresponding side of the electronic device's housing. On the opposing side of the case 100 there is a gap 804 between the two provided side segments 801 and 802. This gap 804 can serve, for example, to accommodate side-mounted buttons/switches on the electronic device. Accordingly, whether to include such a gap, how many gaps, and the sizing and shape of such a gap can vary to accommodate the specific requirements of a given electronic device.

Also in this example it will be noted that the case 100 lacks side segments for the top and bottom sides thereof. If desired, side segments can be provided for these portions of the case 100. For many application settings, however, it can be beneficial to leave these areas open to accommodate, for example, various buttons, switches, and other interfaces as may be present in these areas on a given electronic device.

The aforementioned portions of the case 100 can be comprised, for example, of a suitable plastic and can comprise a unitary, integral molded component. By one approach, if desired, the plastic can comprise antimicrobial plastic (for example, plastic containing silver ions) as is known in the art. This plastic portion of the case 100 can comprise any of a variety of colors as desired and can be smooth and/or textured as desired.

The shell 100 also includes an antimicrobial metal sheet 103 that comprises an antimicrobial metal exterior that covers at least a majority portion of the backside of the electronic device. The antimicrobial properties of certain metals, including copper, silver, and zinc (along with various alloys formed using such metals) are well known in the art. These materials have a documented ability to kill microbes that contact such materials. This action often occurs within two hours of sustained contact and sometimes within as short a time as thirty minutes. The United States Environmental Protection Agency has registered hundreds of different copper alloys, for example, as “antimicrobial materials” in recognition of this property. (As used herein, the expression “antimicrobial metal” will be understood to include both pure antimicrobial metal elements as well as any corresponding alloy that exhibits antimicrobial properties.) For purposes of the current illustrative example it is presumed that the antimicrobial metal sheet 103 comprises a sheet of antimicrobial copper.

By one approach the antimicrobial metal sheet 103 can be coextensive with the aforementioned plastic portion of the case 100. In the illustrated example such is not the case. Instead, various areas of the plastic portion of the case 100 (such as the portions denoted by reference numerals 104 and 105) are free of the antimicrobial metal sheet 103. These non-metal areas 104 and 105 correspond to portions of the corresponding electronic device where one or more antennas are located to facilitate wireless communications (such as, for example, any of a variety of telephony-based wireless communications, Wi-Fi communications, Bluetooth® communications, and so forth). Accordingly, the antimicrobial metal sheet 103 is disposed so as to not interfere with the wireless communications of the electronic device.

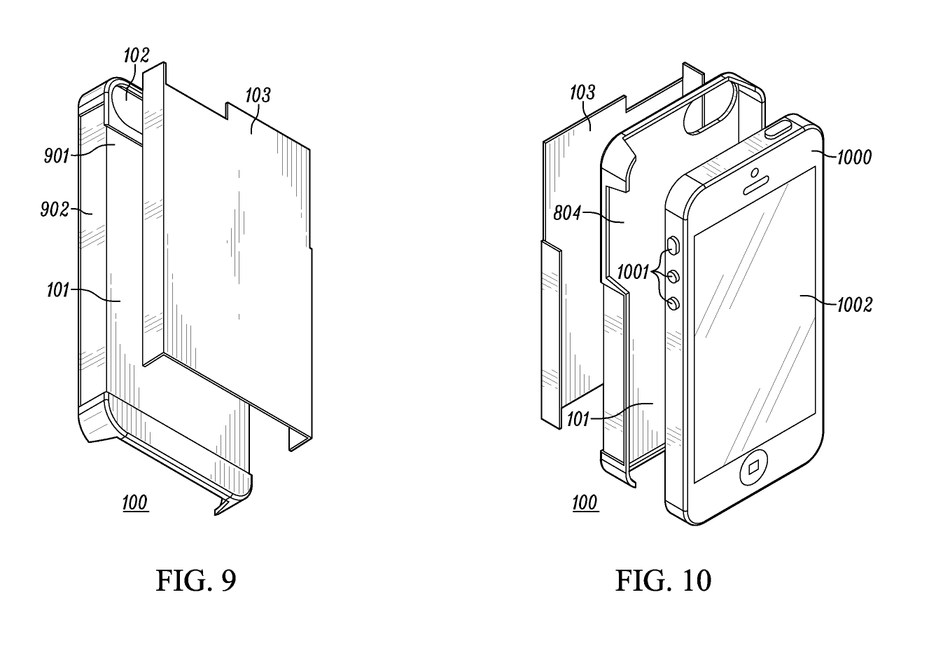

By one approach, if desired, the antimicrobial metal exterior of the case 100 can comprise a plurality of discrete pieces. By another approach, and as illustrated, the antimicrobial metal exterior can comprise a single, unitary component (having, for example, bent edges to wrap around the case 100 where and as appropriate). FIG. 9 provides a particularly helpful view in these regards. By one approach the plastic portion of the case 100 includes recessed areas (as denoted, for example, by reference numerals 901 and 902) to conformally receive the antimicrobial metal sheet 103 such that the exterior surface is coplanar with the exterior surface of the adjacent plastic material to thereby provide a smooth, uninterrupted exterior surface and feel.

The antimicrobial metal sheet 103 can be secured to the plastic portion of the case 100 using any suitable securement mechanism of choice. By one approach, for example, the antimicrobial metal sheet 103 can be snap-fit into the plastic portion. By another approach, in lieu of the foregoing or in combination therewith, the antimicrobial metal sheet 103 can be secured in place using an adhesive of choice.

FIG. 10 depicts an exploded view of the case 100 in conjunction with a corresponding electronic device 1000 (in this illustrative example an iPhone). It can be readily observed that a majority portion of the iPhone's backside will be covered by the antimicrobial metal exterior of the case 100. At the same time, antennas located within the iPhone at its top and bottom are not covered by that metal and hence can operate with little or no interference in those regards. FIG. 10 also helps to illustrate how the aforementioned gap 804 in a side of the case 100 can receive a portion of the electronic device 1000 having various buttons/switches to thereby permit ready user access to those user interfaces even when the case 100 is installed on the device 1000.

The display of an electronic device such as the iPhone consumes a significant portion of the front side thereof. By one approach, if desired, these teachings will accommodate a shell 100 that further includes a transparent shield 1002 made of a suitable transparent plastic and having antimicrobial content (such as silver ions) integrally disposed therein. By one approach this transparent shield 1002 can comprise a stand-alone component that adheres to the display in a manner akin to any of a variety of known screen protectors. By another approach the transparent shield 1002 can comprise an integral part of the case 100 as when the case 100 comprises a two-halved case that receives and fully envelopes the electronic device 1000 (employing a form factor, for example, similar to the well-known Lifeproof® case).

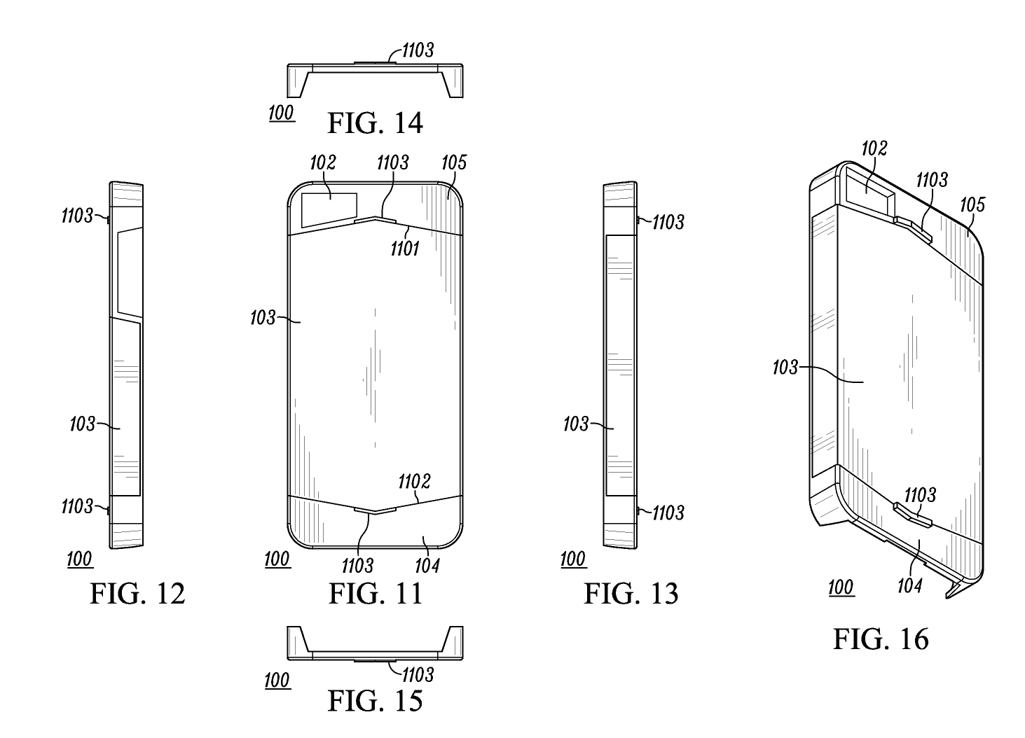

These teachings are highly flexible in practice and will accommodate a wide variety of variations to suit any number of technical and/or aesthetic considerations as characterize a given application setting. As one example in these regards, and referring to FIGS. 11-16, the aforementioned antimicrobial metal sheet 1003 can employ a chevron form factor at the top 1101 and bottom 1102 thereof (while still leaving portions 104 and 105 of the backside of the case 100 non-metalized in order to again avoid interfering with the wireless communications of the encased electronic device 1000).

As another example in these regards, and with continued reference to FIGS. 11-16, the shell 100 in general (and in particular the antimicrobial metal sheet 103) can include one or more raised surfaces 1103 that are configured to interpose between a majority of the shell 100 and a surface (such as a planar surface such as a desk top, table top, counter top, tray top, or the like) upon which the shell 100 is placed. In the illustrated example there are two such raised surfaces 1103 each comprising a V-shaped ridge disposed along a periphery of the antimicrobial metal sheet 103 at opposing ends thereof. Such a configuration can help to avoid having a significant portion of the case 100 contact the supporting surface and hence can further help to minimize the transfer of microbes there between.

And as yet another illustrative example in these regards, these teachings will readily accommodate any of a variety of cosmetic treatments for the antimicrobial metal sheet 103. While applied layers of material that will tend to seal the exterior surface (such as paint, lacquer, or the like) should be avoided as such a layer will isolate the antimicrobial surface from the exterior of the case 100, the metal can nevertheless be “stained” by, for example, exposing the metal to a zinc solution to change the lightness/darkness of the metal's color. As another example the antimicrobial metal sheet 103 can be cosmetically etched to provide a particular look and/or feel to the material.

These teachings will also accommodate embellishing the antimicrobial metal sheet 103 with any of a variety of visually-perceptible informational content such as text, logos, icons, and so forth. Such embellishments can be achieved using, for example, chemical, mechanical, and/or optical etching techniques as are known in the art. These teachings will also accommodate inserting inlays comprised of a different antimicrobial metal. For example, when the antimicrobial metal sheet 103 comprises a copper alloy, a small logo can be formed on the exterior surface thereof by inlaying silver in the shape of that logo. (Inlaying a first type of metal in a second type of metal comprises a known area of endeavor; accordingly no further elaboration is provided here in these regards for the sake of brevity.)

So configured, a shell can be configured to be conformally disposed over at least a majority of a backside of the housing of an electronic device, which shell comprises in part a plastic interior and an antimicrobial metal exterior that itself covers at least a majority portion of the backside of that electronic device. The antimicrobial properties of the metal exterior, in turn, can help to prevent or at least diminish the transfer of potentially-harmful microbes from one location to another during use of the electronic device. At the same time such a shell will not inhibit ordinary use of the electronic device, and provides in particular convenient unimpeded access to the physical user interfaces of the electronic device and does not unduly interfere with the wireless communications capability of the electronic device.

These teachings are also readily scalable and will accommodate a variety of differently-sized electronic devices as well as differently-shaped electronic devices.

By one approach the case can be distributed through at least part of the supply chain in a sterile state. As one example, the case can be pre-sterilized and then placed in an asepsis state into pre-sterilized packaging (such as a hermetically sealed plastic bag, blister pack, and so forth). As another example, the case can be placed in its package and then sterilized. These teachings will accommodate a variety of sterilization methods including any of a variety of chemical techniques (such as exposure to ethylene oxide or hydrogen peroxide vapor), physical techniques (such as sterilization by dry or moist heat, and/or irradiation techniques (such as gamma, electron beam, and microwave irradiation) to note but a few examples in these regards. The packaging itself can comprise, if desired, sealed foil material (or have other “sterile” indicators) to intrinsically visually represent or suggest to the purchaser or other recipient the sterilized nature of the package's contents. In lieu of the foregoing or in combination therewith the case can also be distributed in combination with one or more antiseptic wipes.

Those skilled in the art will recognize that a wide variety of modifications, alterations, and combinations can be made with respect to the above described embodiments without departing from the scope of the invention, and that such modifications, alterations, and combinations are to be viewed as being within the ambit of the inventive concept.

What is claimed is:

1. An apparatus for use with an electronic device having a housing, the apparatus comprising:
a shell configured to be conformally disposed over at least a majority of a backside of the housing, the shell comprised at least in part of a plastic interior and an antimicrobial metal exterior that covers at least a majority portion of the backside of the electronic device.

2. The apparatus of claim 1 wherein the shell is further configured to extend over at least a portion of at least one side of the housing.

3. The apparatus of claim 2 wherein the shell is further configured to extend over at least a portion of two sides of the housing.

4. The apparatus of claim 3 wherein at least portions of the shell that extend over the sides of the housing also have an antimicrobial metal exterior.

5. The apparatus of claim 1 wherein the antimicrobial metal exterior comprises at least one of copper, silver, and zinc.

6. The apparatus of claim 1 wherein the antimicrobial metal exterior comprises a metal sheet that is attached to the plastic interior.

7. The apparatus of claim 1 wherein the shell is configured to snap-fit onto the housing.

8. The apparatus of claim 1 wherein the shell further comprises a raised surface on the shell configured to interpose between a majority of the shell and a surface upon which the shell is placed.

9. The apparatus of claim 8 wherein the raised surface comprises a ridge disposed along a periphery of the antimicrobial metal exterior.

10. The apparatus of claim 1 wherein plastic portions of the shell comprise antimicrobial plastic.

11. The apparatus of claim 1 wherein the electronic device uses at least one radio-frequency carrier to communicate wirelessly.

12. The apparatus of claim 11 wherein the antimicrobial metal exterior is disposed so as to not interfere with the wireless communications of the electronic device.

13. The apparatus of claim 11 wherein the electronic device comprises a portable, wireless telephony device.

14. The apparatus of claim 1 wherein the electronic device includes a display and wherein the shell further comprises a transparent shield that overlies the display.

15. The apparatus of claim 14 wherein the transparent shield includes antimicrobial content.

16. The apparatus of claim 15 wherein the antimicrobial content includes silver ions.

17. The apparatus of claim 1 wherein the antimicrobial metal exterior includes at least an exposed surface portion thereof that is cosmetically treated.

18. The apparatus of claim 1 wherein the antimicrobial metal exterior includes cosmetic etching.

19. The apparatus of claim 1 wherein the antimicrobial metal exterior includes inlays comprised of a different antimicrobial metal.
